(19) United States
(12) Patent Application Publication
(10) Pub. No.: US 2026/0182316 A1
(43) Pub. Date: Jun. 25, 2026

(54) METHOD FOR STRESSING THE BOX BY CREEP

(71) Applicant: COMMISSARIAT A L'ENERGIE ATOMIQUE ET AUX ENERGIES ALTERNATIVES, Paris (FR)

(72) Inventors: Sylvie JARJAYES, Grenoble Cedex 09 (FR); Claire FENOUILLET-BERANGER, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/426,178

(22) Filed: Dec. 19, 2025

(30) Foreign Application Priority Data
Dec. 23, 2024 (FR) FR2415182

(51) Int. Cl. H10P 95/40; H10P 95/90

(52) U.S. Cl. CPC H10P 95/40; H10P 95/90

(57) ABSTRACT

Aspects of the present disclosure provide a method for fabricating a device with strained semiconductor regions, including coating a semiconductor layer of a substrate of the semiconductor on insulator type with a stressing layer made of an amorphous material having a tensile intrinsic strain, forming, in the stressing layer, at least one opening facing a first semiconductor region of said semiconductor layer, and carrying out a creep annealing according to a duration and a temperature adapted to allow the creep of the insulating layer of the substrate and tension the first semiconductor region.

### TECHNICAL FIELD AND PRIOR ART

The present description relates to the field of microelectronics and semiconductor devices provided with one or more strained semiconductor regions.

It is aimed particularly at that of the methods for making such devices and the methods for straining or relaxing a semiconductor region.

To improve the performance of certain microelectronic components, in particular transistors, it can be advantageous to provide for the latter to be made partly in a layer of semiconductor material in which a tensile or compressive mechanical strain is applied.

Mechanical strain of a semiconductor layer means that the crystal lattice parameter(s) of its material are deformed.

In the case in which the deformed lattice parameter is greater than the “natural” parameter of a crystalline material in a given direction, the latter is said to be in tensile deformation in this direction.

When the deformed lattice parameter is smaller than the natural lattice parameter, the material is said to be in compressive deformation or compressed.

States of mechanical strain are associated with these states of mechanical deformation.

The band structure of a semiconductor material subjected to a given strain state is modified, which engenders a modification of the electrical properties of this material, in particular of the mobility of the carriers in this material. The same semiconductor material is affected differently according to its doping type and its crystallographic orientation.

Thus, to improve the performance of transistors, it is possible for their channel region to be made of a semiconductor material having a tensile or compressive biaxial mechanical strain according to whether it is a p-doped (the majority of carriers being holes) or n-doped (the majority of carriers being electrons) semiconductor.

To apply a strain onto a region of semiconductor material, it is known to use a method commonly called “BOX creep” in which a layer of thermal oxide commonly called “BOX” (for “Buried Oxide”) is used in a substrate of the insulating semiconductor type to allow to apply a strain to a semiconductor layer.

This involves taking advantage of the sharp drop in the viscosity of the BOX at high temperature by carrying out a thermal annealing during which a relaxing of the strains is possible due to the creep of the BOX.

The document US2008169508A1 uses such a method with a particular creep or BOX layer made of BPSG (“BoroPhosphoSilicate Glass”), in a method in which, by structuring a semiconductor layer, a semiconductor island under a tensile strain and a semiconductor island under a compressive strain are formed on which a stressing layer containing SiN having an intrinsic compressive strain and a stressing layer containing SiN having an intrinsic tensile strain have been formed, respectively, which are relaxed following a creep heat treatment allowing to modify the viscoelastic properties of the layer of BPSG.

The method implemented here has in particular the disadvantage of using a doped BOX layer and requiring the implementation of two different nitride layers obtained by different methods to obtain different strains to the N and P zones of a given substrate.

As for the document US2020/0066909 A1, it presents another method in which the BOX creep method is used this time on a non-doped BOX layer which requires the use of higher temperatures to carry out the creep heat treatments. However, in the case of heat treatment at high temperature, in particular above 600° C., it is difficult to preserve the intrinsic strain of a stressing layer made of compressive nitride.

The problem arises of finding a new method, preferably improved with respect to at least one of the disadvantages mentioned above, allowing to modify the strain state of one or more semiconductor regions of different types (N or P) while limiting the number of steps necessary for this.

### DISCLOSURE OF THE INVENTION

It is consequently a goal of the present invention to propose a method for modifying the strain state of at least one semiconductor region of a semiconductor device, the method comprising, in this order, the following steps:
a) coating a “surface” semiconductor layer of a substrate of the semiconductor on insulator type with a stressing layer, the substrate comprising: a support layer, an insulating layer resting on the support layer and the surface semiconductor layer resting on the insulating layer, then
b) forming, in the stressing layer, at least one opening passing through the stressing layer and arranged facing a first semiconductor region of the surface semiconductor layer while preserving at least a portion of the stressing layer on and facing at least a part of the substrate disposed against and in contact with the first semiconductor region, then
c) carrying out a “creep” annealing according to a duration and a temperature adapted to allow the creep of the insulating layer of the substrate and relax the portion of the stressing layer so as to modify a strain state of the first semiconductor region.

With such a method it is possible to apply a strain, or increase the strain or optionally relax a semiconductor region.

Here, the strain state of at least one region of the surface layer is modified without having to carry out a significant number of steps.

Typically, insulation zones containing insulating material such as isolation trenches are provided.

Thus, advantageously, in step a), the substrate comprises insulation zones containing insulating material passing through the “surface” semiconductor layer, in particular isolation trenches arranged on either side of an “active” semiconductor zone comprising the first semiconductor region.

The fact that in step a), the substrate already comprises insulation zones allows to maximize the strain in the first semiconductor region which is located facing the opening.

Advantageously, the opening arranged facing the first semiconductor region is centered with respect to a first isolation trench and a second isolation trench disposed on either side of the first semiconductor region.

The opening passing through the stressing layer can be created so as to preserve a second portion of the stressing layer, the portion of the stressing layer and the second portion thus being arranged on either side of the opening.

The portion of the stressing layer and the second portion of the stressing layer can be arranged respectively facing a second semiconductor region and a third region of the surface semiconductor layer disposed against and in contact with the first semiconductor region, the second semiconductor region and the third semiconductor region being arranged on either side of the first semiconductor region.

The preserved portion of the stressing layer can be provided so as to overlap the second semiconductor region and the first isolation trench, while the second portion of the stressing layer overlaps the third semiconductor region and the second isolation trench.

It is thus possible to advantageously create with different strained regions, in particular tensile and compressive without necessarily having to deposit several different stressing layers and having to use various materials having different intrinsic strains.

According to a specific embodiment, the stressing layer in which the opening is formed in step b) comprises a tensile strain. In this case, the creep annealing of the insulating layer of the substrate and the relaxing of the portions of the stressing layer can cause a compression of the second semiconductor region and of the third semiconductor region and a tension of the first semiconductor region.

According to one implementation possibility, the first semiconductor region belongs to a semiconductor zone called “active zone” intended to house at least one transistor of the N type, and the opening can be made so as to preserve a portion of the stressing layer facing another active zone, the other active zone being intended to house one or more transistors of the P type.

According to a specific embodiment, after formation of the opening and before the creep annealing, the method can further comprise the deposition of a second stressing layer on the stressing layer as well as on the first semiconductor region.

According to one implementation possibility, a second opening exposing another semiconductor region of said surface semiconductor layer can be formed in the stressing layer, the opening and the second opening having different respective dimensions.

According to an embodiment in which, prior to the step of creep annealing, a part of the substrate is coated with a second stressing layer different from said stressing layer and/or having a different thickness than the stressing layer, the method can further comprise, prior to the step of creep annealing, the creation of an opening in the second stressing layer exposing another semiconductor region of the surface semiconductor layer.

According to a specific embodiment, the material of the stressing layer can be silicon nitride under a tensile strain.

Here, a stressing layer made of material having a tensile intrinsic strain is used which, contrary to the nitride under a compressive strain, can be preserved at high temperature, and this layer is structured to subsequently allow to obtain a semiconductor region under a tensile strain after the creep.

Typically, the stressing layer can be provided with a thickness between 20 nm and 100 nm.

According to one implementation possibility, the creep annealing in step b) is carried out at a temperature between 900° C. and 1200° C., in particular for a duration between 1 and 30 minutes.

According to a specific embodiment, the first semiconductor region contains Si, and wherein at least one other semiconductor zone of the substrate coated by the stressing layer is made of SiₓGe₁₋ₓ (with 0<x<1).

Advantageously, this at least one other semiconductor zone is enriched with germanium from the surface semiconductor layer, the surface semiconductor layer being made of silicon. In this case, the method can comprise, before step a), steps of:
forming a block made of silicon germanium, on the other semiconductor zone,
thermally oxidizing the semiconductor block made of silicon germanium and said surface semiconductor layer so as to carry out an enrichment of the other semiconductor zone with germanium.

According to another aspect, the invention provides a method for producing a device with transistors using a method as defined above and in particular comprising:
implementing a method as defined above then, after the step c) of creep annealing,
removing the stressing layer, the method further comprising, after removal of the stressing layer: forming at least one transistor in the first semiconductor region and at least one other transistor in another semiconductor region of the surface layer of the substrate.

### BRIEF DESCRIPTION OF THE DRAWINGS

The present invention will be better understood on the basis of the following description and the appended drawings in which:

FIGS. 1A, 1B, 1C and 1D are used to illustrate an exemplary embodiment of a method according to the invention, for producing a structure comprising a semiconductor region under stress, here tensile, with semiconductor regions on either side strained differently, in this example compressively, from a substrate of the semiconductor on insulator type by implementing a BOX creep step.

FIGS. 1E and 1F are used to illustrate the production of N-type transistors and P-type transistors on such a structure.

FIGS. 2A and 2B are used to illustrate an alternative embodiment in which a region containing silicon under tension and on either side compressively strained regions made of SiₓGe₁₋ₓ are formed.

FIG. 3 is used to illustrate a structure for the implementation of a condensation of germanium in order to form regions made of SiₓGe₁₋ₓ intended to be compressively strained.

FIG. 4 is used to illustrate the implementation of several openings in a stressing layer and facing the same active zone in order to form in this active zone several portions under a tensile strain distributed facing the openings.

FIGS. 5, 6, 7, 8, 9 and 10 are used to illustrate the influence of various parameters on the level and distribution of strain(s) in an active zone obtained by implementing a method according to the invention.

FIGS. 11A, 11B and 11C are used to illustrate an alternative embodiment.

FIG. 12 is used to illustrate an alternative method in which stressing layers containing different materials are provided on various parts of a substrate.

FIG. 13 is used to illustrate an alternative method in which stressing layers having different respective thicknesses are provided on various parts of a substrate.

FIG. 14 is used to illustrate an alternative method in which openings having different respective dimensions facing various parts of a substrate are provided in a stressing layer.

Identical, similar or equivalent parts of the various figures bear the same numerical references so as to facilitate the transition from one figure to another.

The various parts shown in the drawings are not necessarily shown according to a uniform scale, to make the drawings more readable.

Furthermore, in the description below, terms that depend on the orientation of a structure such as “front”, “rear”, “upper”, “lower”, “on”, “under”, “on top”, “underneath”, “above”, “below” apply when considering that the structure is oriented as illustrated in the figures.

### DETAILED DISCLOSURE OF SPECIFIC EMBODIMENTS

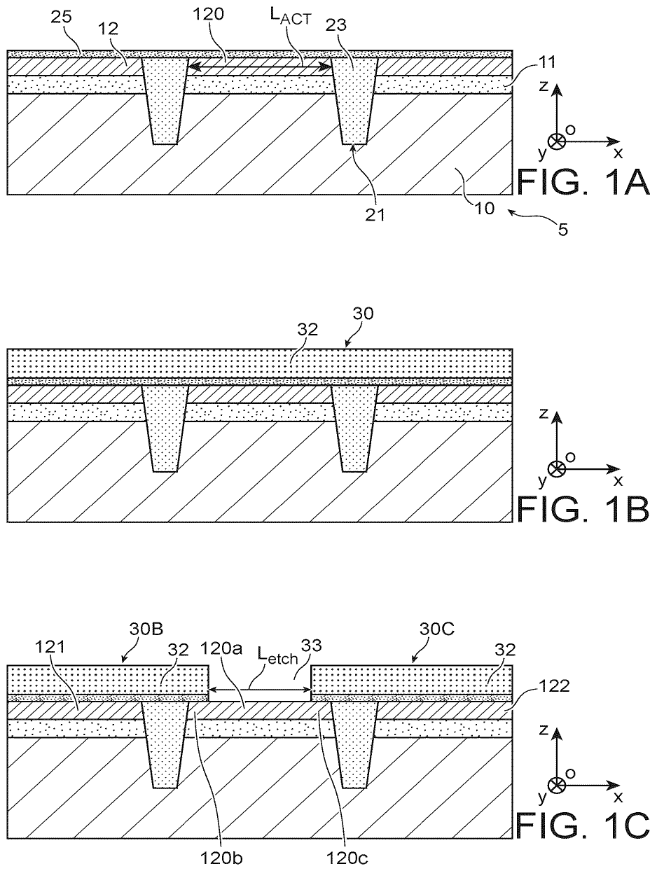

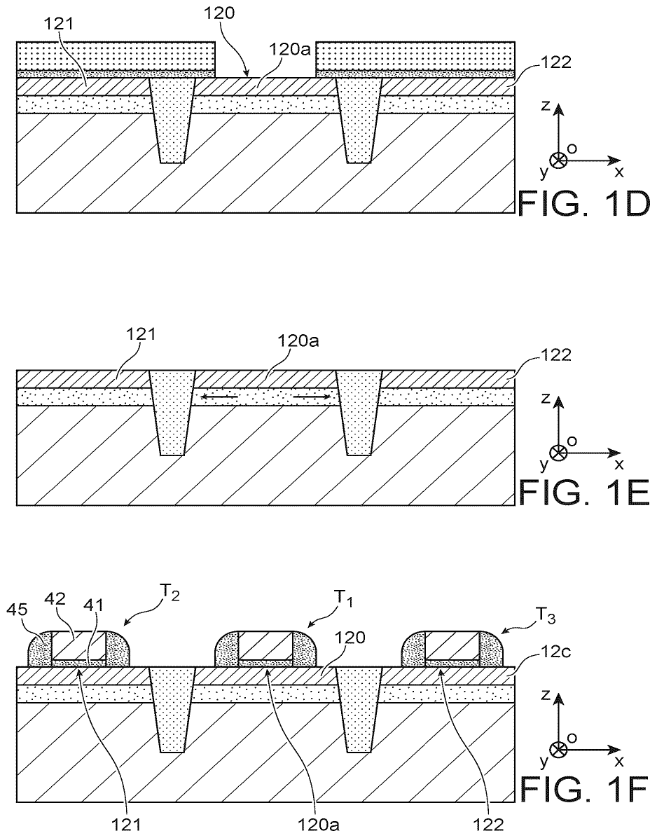

Reference is now made to FIG. 1A which gives an example of a starting structure of a method for producing a semiconductor device comprising one or more strained semiconductor regions and here in particular at least one semiconductor region under a tensile strain.

The structure comprises a substrate 5 of the semiconductor on insulator type, for example of the SOI type (SOI for “silicon on insulator”). The substrate 5 is thus provided with a support layer 10, typically semiconductor, which can contain silicon, as well as an insulating layer 11, which is disposed on and in contact with the support layer 10, and a “surface” semiconductor layer 12 located on and in contact with said insulating layer 11 and in which, typically, transistors are intended to be formed.

The surface semiconductor layer 12 can have a thickness for example between 5 and 20 nm, preferably between 5 and 10 nm.

The insulating layer 11 typically contains silicon oxide, preferably undoped or unintentionally doped. This insulating layer 11 can be provided with a thickness for example between 10 and 30 nm, preferably between 15 and 25 nm.

Insulation zones allowing to define several active zones can also be made in and/or on the substrate 5.

In the specific exemplary embodiment of FIG. 1A, these insulation zones are in the form of STI (for “Shallow Trench Isolation”) isolation trenches 21. To manufacture such isolation trenches, trenches are dug through the “surface” semiconductor layer 12, the insulating layer 11, and the bottom of which is located at the level of the support layer 10. Then, these trenches 21 are filled using an insulating material 23, for example silicon oxide.

Alternatively, insulation zones of another type can be provided. For example, “mesa” insulation zones involving the manufacturing of insulating structures on the surface of the surface semiconductor layer 12 can be produced.

A semiconductor zone 120 located between the isolation trenches 21 can be provided to form an active zone in which one or more transistors are intended to be formed, in particular transistors of the N type. Such a zone 120 can have a length L_{ACT} (dimension measured here from one STI zone to another and parallel to the axis x of an orthogonal coordinate system [O°;x°;y°;z°]) for example between 100 nm and 10000 nm and typically corresponding to dimensions provided by design rules of a targeted technology node.

In the specific exemplary embodiment illustrated in FIG. 1A, the substrate 5 is also coated with a thin insulating layer 25 which can here for example contain SiO₂. The thin insulating layer 25 can be created after deposition of the material 23 then planarization by CMP (“Chemical Mechanical Planarization”), removal of a hard mask for example containing nitride used to carry out a CMP polishing.

Such a thin insulating layer 25 can act as a buffer and be used to prevent a possible degradation of the surface semiconductor layer 12 by preventing in particular the appearance of dislocations, in particular during subsequent annealing steps, in particular at high temperature.

A stressing layer 30 is then formed from a material 32 having a tensile strain (FIG. 1B). For example, such a layer can be formed by a technique of the type CVD (for “Chemical vapor deposition”) or LPCVD (for “Low Pressure Chemical Vapor Deposition”) or PECVD (“Plasma Enhanced CVD”). The stressing layer 30 can be deposited with an intrinsic strain, in particular a tensile strain.

Thus, the material 32 can for example be silicon nitride (SiₓN_{y}) with a tensile intrinsic strain. This strain can for example be between 0.5 GPa and 1.5 GPa for a stressing layer 30 provided with a thickness which can be for example between 20 nm and 100 nm.

An opening 33 passing through the stressing layer 30 is then formed in the stressing layer 30. The opening 33 here exposes a semiconductor region 120a of the surface semiconductor layer 12 which is located between the STI isolation trenches 21 and belongs to the active zone 120. The opening 33 created is provided with a critical dimension L_{etch} (smallest dimension of the opening 33 in a plane parallel to the axis x of an orthogonal coordinate system [O°;x°;y°;z″]) which can be for example between 10 nm and the length L_{ACT} of the first active zone. Advantageously, L_{etch}≤Lact−10 nm.

Preferably, the critical dimension L_{etch} is provided as less than the length L_{ACT} of the active zone. The difference in dimension between the critical dimension L_{etch} and the length L_{ACT} can be at least one or more tens of nanometers. For example, when implementing an active zone having a length L_{ACT} of approximately 500 nm, an opening having a critical dimension L_{etch} of approximately 400 nm can be provided.

In this exemplary embodiment, portions 30B, 30C of the stressing layer 30 are preserved facing regions 120b, 120c, respectively, of the surface semiconductor zone 120 disposed on either side of the region 120a exposed by the opening 33. Here advantageously the preserved portions 30B, 30C of the stressing layer 30 disposed on either side of the opening 33 overlap both the regions 120b, 120c of the surface semiconductor zone 120 and the STI isolation trenches. In other words, the portion 30B extends continuously facing the region 120b of the surface semiconductor zone 120 and an STI isolation trench 21, while the portion 30C extends continuously facing the region 120c of the surface semiconductor zone 120 and another STI isolation trench 21.

The opening 33 facing the region 120a is here advantageously centered with respect to the STI isolation trenches, so that it is located at an equal distance between a first STI isolation trench and a second isolation trench disposed on either side of the region 120a.

Such an opening 33 can be formed by photolithography by creating a masking containing photosensitive resin, then by etching by reproducing patterns created by the masking in the stressing layer 30 here containing nitride and in the specific example described here, in the optional thin insulating layer 25.

Then (FIG. 1D), a heat treatment, for example in an annealing furnace, is carried out at a temperature, preferably high, and according to a duration chosen so as to modify the viscoelastic behavior of the material of the insulating layer 11 and in particular decrease its viscosity.

To cause the creep of the insulating layer 11, the annealing treatment is preferably carried out at “high temperature”, that is to say greater than or equal to 900° C. Preferably, the temperature of this annealing is chosen as less than 1200° C. so as to not risk damaging the substrate.

The degree of deformation due to the creep increases as the duration of the high-temperature annealing treatment increases and as the temperature at which the high-temperature annealing treatment is carried out increases.

The creep of the insulating layer 11 causes a modification of the strain state of the semiconductor layer 12. Due to the creep annealing, the portions 30B, 30C of the tensile straining layer arranged on either side also tend to relax, which promotes the stretching of the lattice of the material of the semiconductor region 120a. The semiconductor region 120a facing which the stressing layer 30 has been removed thus undergoes a tensile strain.

The annealing time can be adapted according to the geometry of the zone 120 and of the underlying insulating layer 11, and the type of material forming this insulating layer 11. The duration of the creep annealing can be for example between 1 and 30 minutes.

Such creep also promotes the shrinking of the lattice of the material of the semiconductor regions 120b, 120c and consequently a compression of the semiconductor regions 120b, 120c located on either side of the semiconductor region 120a.

The level of strain in the surface semiconductor layer 12 and in particular of tension in the semiconductor region 120a depends on and can be adjusted according to the chosen thickness of the stressing layer 30 and/or the intrinsic strain level of the material 32, itself being dependent on parameters of the method of deposition of the material 32 which can be adjusted.

Once this creep annealing has been carried out, the stressing layer 30 can then be removed.

Such a removal can be carried out for example by dry or wet etching when the material 33 contains silicon nitride.

In the case in which the thin insulating layer 25 covers the surface semiconductor layer 12, this thin insulating layer 25 is then also removed (FIG. 1E). Such a removal can be carried out for example by etching using HF or a plasma using a fluorinated gas, in particular when this thin layer is made of oxide.

Transistors T₁, T₂, T₃ can then be formed on the structure obtained and provided with at least one semiconductor region 120a under a tensile strain.

In particular, at least one transistor T₁ of the N type, the channel of which extends in the tensed semiconductor region 120a, and one or more transistors T₂, T₃ of the P type in semiconductor zones 121, 122 located on either side of the semiconductor zone 120 and compressed after the creep annealing due to the relaxing of the portions 308, 30C located above these semiconductor zones 121, 122 are provided.

The creation of the transistors can comprise in particular steps of forming a gate dielectric 41 and a gate block 42 facing each of the semiconductor zones 120, 121, 122 using steps of deposition, photolithography and etching, then forming insulating spacers on either side of the gate block (FIG. 1F). A doping of the source and drain regions can then be carried out. In the case according to which “raised” source and drain regions are created, these regions are typically formed by growth by epitaxy on the semiconductor layer 12. A doping of the source and drain regions can then be carried out at least partially during the epitaxy step.

According to an alternative embodiment of a method as described above and instead of compressing semiconductor zones 121, 122 of a silicon layer, to improve the performances of the transistors of the P type, it is possible to carry out this compression on regions of SiₓGe₁₋ₓ (with 0<x<1).

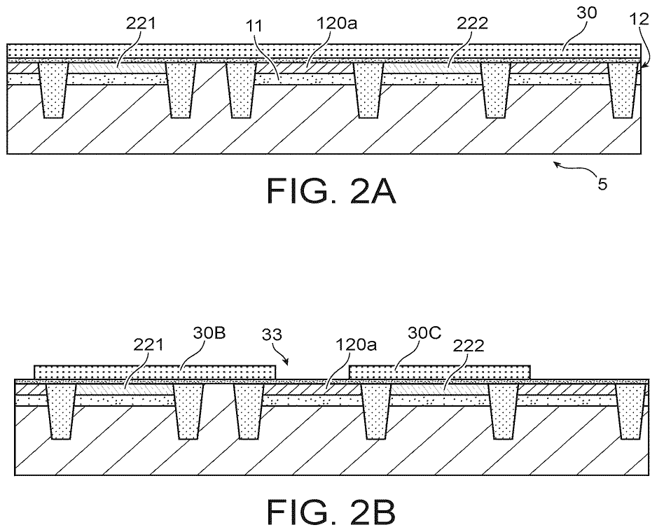

Thus, in the exemplary embodiment given in FIGS. 2A-2B, the stressing layer 30 having a tensile intrinsic strain and typically made of silicon nitride on a semiconductor layer comprising at least one semiconductor zone 120 made of silicon and, on either side of this zone 120, semiconductor regions 221, 222 made of SiₓGe₁₋ₓ are first formed (FIG. 2A).

Then, at least one opening 33 is formed in the stressing layer 30 opposite the semiconductor region 120a and so as to preserve portions 30B, 30C of the stressing layer 30 located respectively opposite the semiconductor zones 221 and 222 made of SiₓGe₁₋ₓ located on either side of the semiconductor zone 120 made of silicon (FIG. 2B).

A creep annealing is then carried out according to a duration and a temperature adapted to allow the creep of the insulating layer 11 of BOX and cause a tensioning of the semiconductor region 120a facing the opening 33 while compressing the semiconductor regions 221, 222 made of SiₓGe₁₋ₓ located opposite the portions 30B, 30C of the stressing layer 30.

One way of creating the semiconductor zones 221, 222 made of SiₓGe₁₋ₓ is to carry out a germanium enrichment of the regions of a surface semiconductor layer 12 made of silicon.

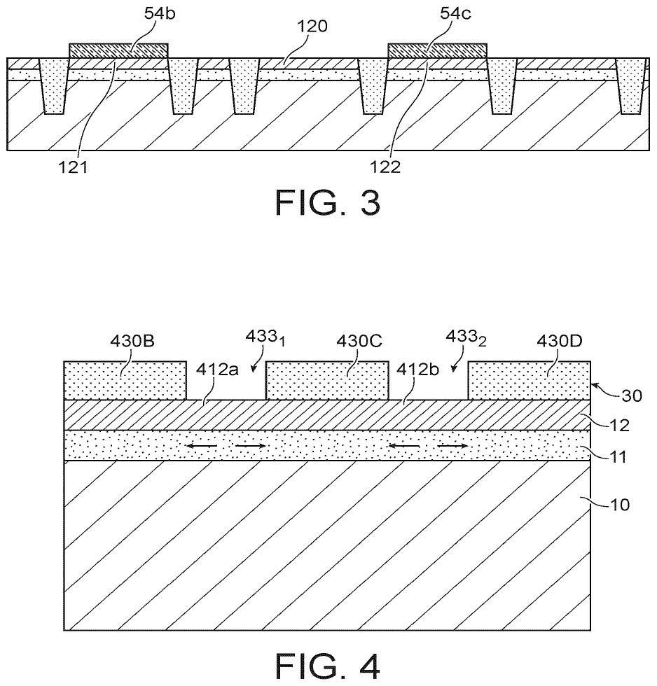

For this, it is possible to start from a substrate 5 of the semiconductor on insulator type, optionally provided with insulation zones, in particular STI trenches, and prior to the creation of the stressing layer 30, blocks 54b, 54c can be formed from silicon germanium, respectively on semiconductor regions 121, 122 of the surface semiconductor layer 12 of the substrate 5 (FIG. 3).

Such blocks can be made, for example, by depositing or growing a layer made of silicon germanium on the surface semiconductor layer 12 then by forming patterns in this layer of silicon germanium. Then, a thermal oxidation of the semiconductor blocks 54b, 54c made of silicon germanium is carried out to allow to make the germanium atoms migrate into portions of the surface layer and to carry out an enrichment of the surface semiconductor layer with germanium. The documents EP2075826B1 and FR2908924A1 from the applicant give examples of a germanium enrichment method, also called germanium condensation method, for forming regions of SiₓGe₁₋ₓ from silicon blocks.

A thickness of oxide formed during the germanium condensation step can then be removed for example by cleaning using HF.

As an alternative to what has just been described, it is also possible to create the isolation zones such as STI trenches after the formation of the regions of SiₓGe₁₋ₓ by germanium condensation or enrichment.

It is possible to provide transistors of the P type in the germanium-enriched regions under a compressive strain and one or more transistors of the N type in the preserved region made of silicon and which is placed under a tensile strain using the creep.

According to a specific exemplary embodiment given in FIG. 4, this time several openings 433₁, 433₂ are made in the stressing layer 30 facing the same active zone.

Thus, several openings 433₁, 433₂ are formed in the stressing layer 30 and between insulating isolation zones, for example of the STI type (not shown in FIG. 4).

In the exemplary embodiment illustrated in FIG. 4, a first opening 433₁ is formed in the stressing layer 30 facing a semiconductor region 412a of said surface semiconductor layer 12 and a second opening 433₂ is formed in the stressing layer 30 facing another semiconductor region 412b of said surface semiconductor layer 12. On either side of these semiconductor regions 412a, 412b exposed by the openings 433₁, 433₂, portions 430B, 430C and 430C, 430D of the stressing layer 30 are preserved.

The high-temperature annealing is then carried out according to a duration and a temperature adapted to allow the creep of the insulating layer 11 of the substrate and relax the portions 4308, 430C, 430C, 430D of the stressing layer 30. Semiconductor regions 412a, 412b located facing the openings 433₁, 433₂ are thus tensioned. Several tensioned regions are thus obtained in particular zones of an active zone.

Such an arrangement and such a distribution of the strains can be implemented for specific uses for example when a transistor is made only facing the tensioned regions 412a, 412b.

As indicated above, the level and the distribution of the strains in the regions of the semiconductor surface layer 12 can be adapted according to certain parameters of the stressing layer 30 and of the opening(s) made in this layer.

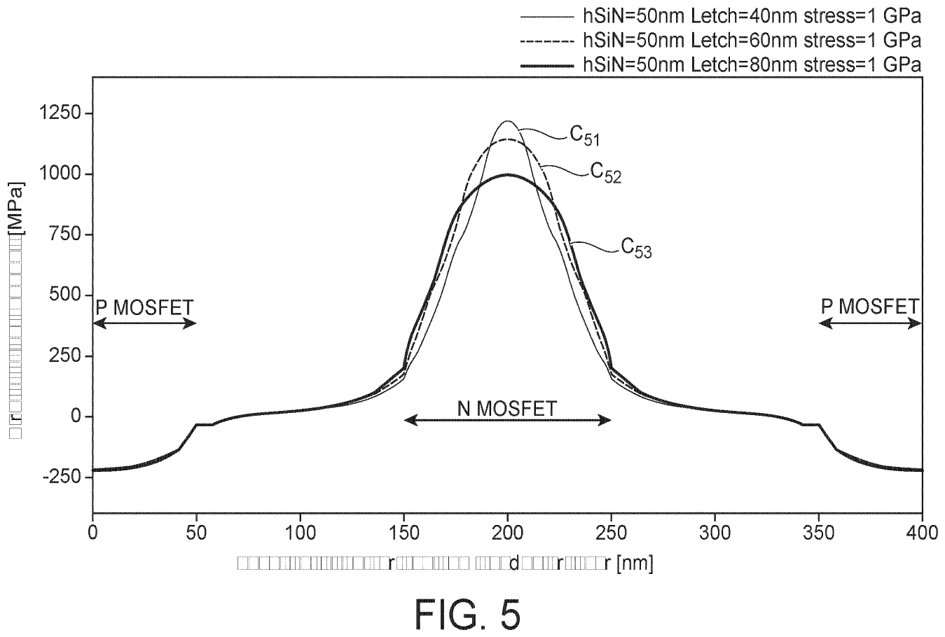

FIG. 5 gives various curves C₅₁, C₅₂, C₅₃ representative of the change in a strain level in the surface semiconductor layer 12 obtained here by simulation using the Ansys Mechanical™ tool for a stressing layer 30 containing nitride having a thickness of 50 nm according to the position in this surface semiconductor layer 12, and for various critical opening dimensions L_{etch} of 40 nm, 60 nm and 80 nm, respectively. The strain level thus varies little according to the value of the critical dimension L_{etch} of the opening.

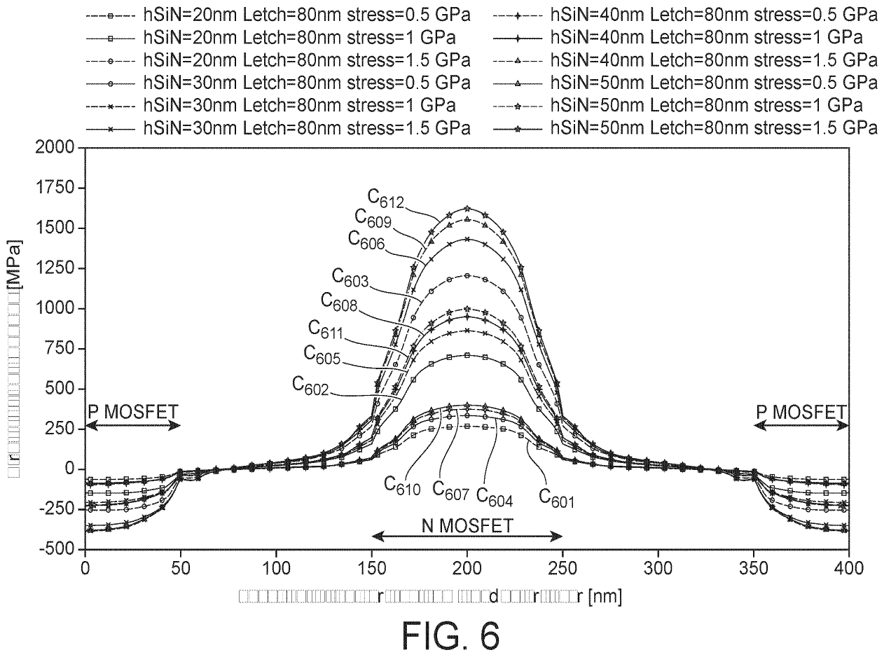

As for FIG. 6, it gives various curves C₆₀₁, C₆₀₂, C₆₀₃, C₆₀₄, C₆₀₅, C₆₀₆, C₆₀₇, C₆₀₈, C₆₀₉, C₆₁₀, C₆₁₁, C₆₁₂, C₆₁₃ representative of the change in a strain level in an active zone having a length L_{act} of 100 nm according to the position in this surface semiconductor layer 12, the strain being obtained using a stressing layer 30 containing nitride in which the opening 33 has a critical dimension L_{etch} of 80 nm and for a creep annealing carried out at 1050° C. for 600 seconds. These curves are obtained for various thicknesses, respectively 20 nm (curves C₆₀₁, C₆₀₂, C₆₀₃), 30 nm (curves C₆₀₄, C₆₀₅, C₆₀₆), 40 nm (curves C₆₀₇, C₆₀₈, C₆₀₉) and 50 nm, of the stressing layer 30 and various intrinsic strain levels, respectively 0.5 GPa (curves C₆₀₁, C₆₀₄, C₆₀₇, C₆₁₀), 1 GPa (curves C₆₀₂, C₆₀₅, C₆₀₈, C₆₁₁), 1.5 GPa (curves C₆₀₃, C₆₀₆, C₆₀₉, C₆₁₂). This FIG. 6 shows the influence of the thickness of the stressing layer and the level of intrinsic strain in this layer to allow an adequate strain transfer in the semiconductor surface layer.

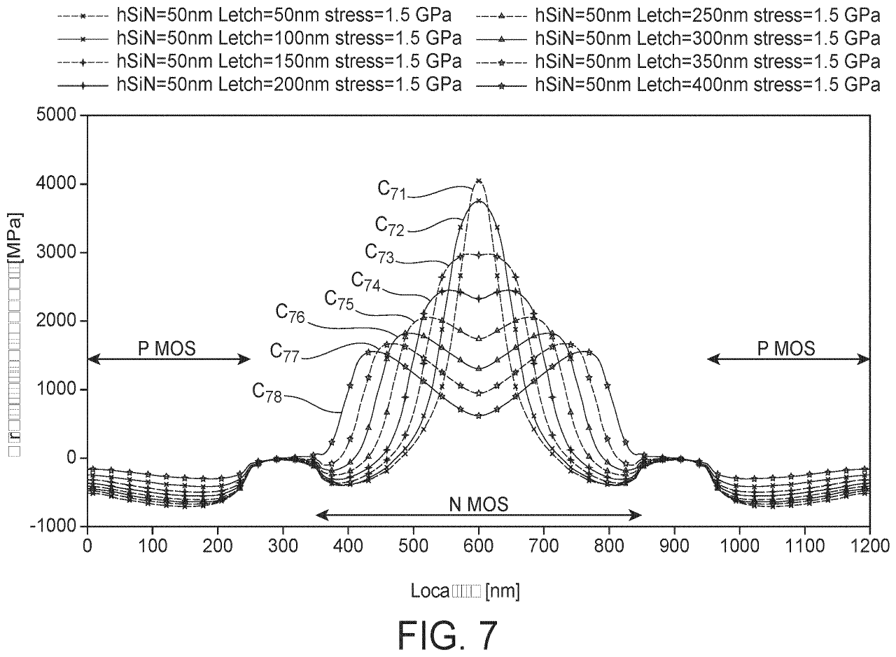

As for FIG. 7, it gives various curves C₇₁, C₇₂, C₇₃, C₇₄, C₇₅, C₇₆, C₇₇, C₇₈, representative of the change in a strain level in an active zone having a length L_{act} of 500 nm according to the position in this surface semiconductor layer 12, the strain being obtained using a stressing layer 30 containing nitride having a thickness of 50 nm, an intrinsic strain level of 1.5 GPa and for various critical dimensions L_{etch}, respectively 50 nm, 100 nm, 150 nm, 200 nm, 250 nm, 300 nm, 350 nm, 400 nm. This drawing teaches that it is preferable to show the impact of the choice of the critical dimension L_{etch} on the strain profile obtained.

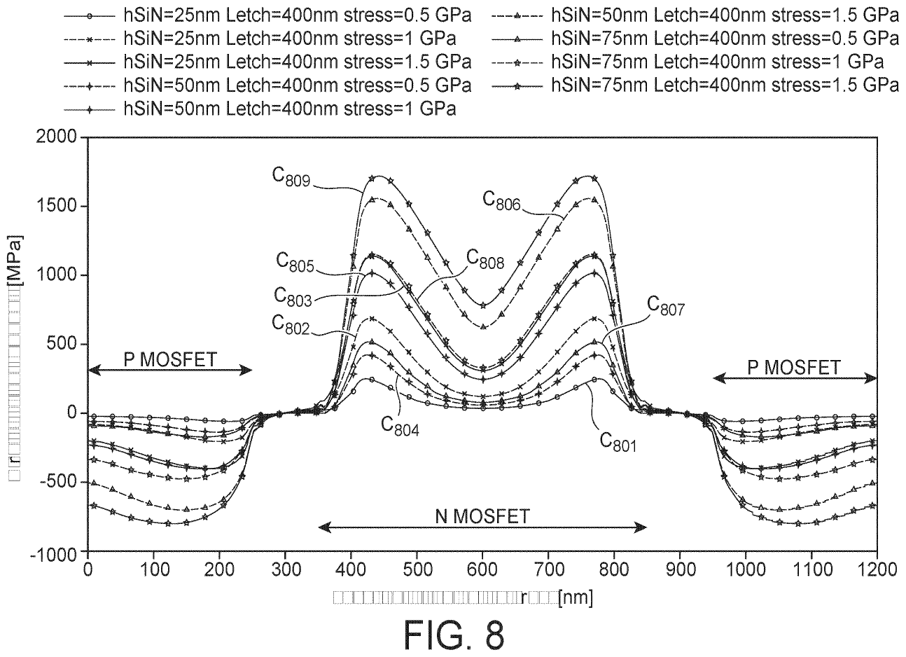

FIG. 8 gives various curves C₈₀₁, C₈₀₂, C₈₀₃, C₈₀₄, C₈₀₅, C₈₀₆, C₈₀₇, C₈₀₈, C₈₀₉, representative of the change in a strain level in an active zone having a length L_{act} of 500 nm according to the position in this surface semiconductor layer 12, the strain being obtained using a stressing layer 30 containing nitride in which at least one opening is made and for a creep annealing carried out at 1050° C. for 600 seconds. These curves are obtained for various thicknesses, respectively 25 nm (curves C₈₀₁, C₈₀₂, C₈₀₃), 50 nm (curves C₈₀₄, C₈₀₅, C₈₀₆), 75 nm (curves C₈₀₇, C₈₀₈, C₈₀₉), and various intrinsic strain levels of 0.5 GPa (curves C₈₀₁, C₈₀₄, C₈₀₇), 1 GPa (curves C₈₀₂, C₈₀₅, C₈₀₈), 1.5 GPa (curves C₈₀₃, C₈₀₆, C₈₀₉). Here again, this figure shows the influence of the thickness of the stressing layer and of the level of intrinsic strain in this layer.

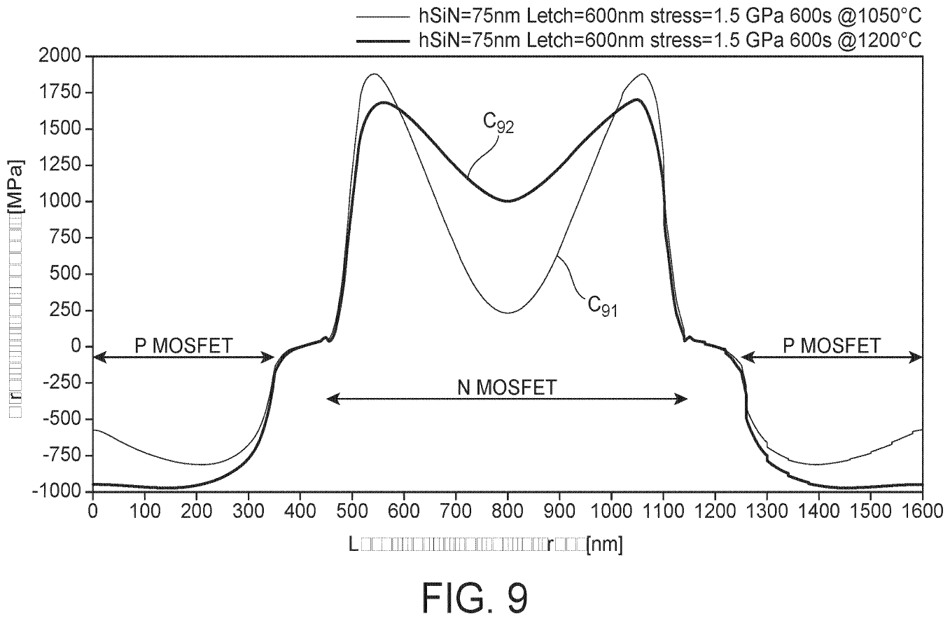

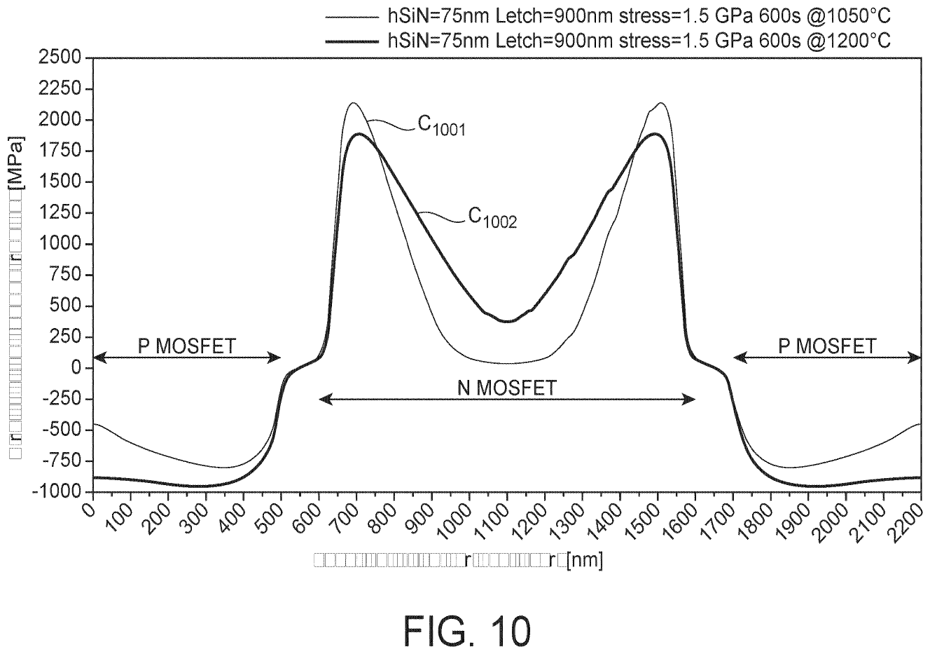

As for the curves C₉₁, C₉₂ of FIGS. 9 and C₁₀₀₁, C₁₀₀₂ of FIG. 10, they are used to illustrate the impact of the creep annealing temperature on the strain level in an active zone having a length L_{act} of 700 nm (curves C₉₁, C₉₂) or in an active zone having a length L_{act} of 1000 nm (curves C₁₀₀₁, C₁₀₀₂), the strain being obtained using a stressing layer 30 containing nitride 75 nm thick and an intrinsic strain level of 1.5 GPa. These curves are obtained for an annealing carried out for a duration of approximately 600 seconds and temperatures of 1050° C. (curve C₉₁, C₁₀₀₁) and 1200° C. (curve C₉₂, C₁₀₀₂), respectively. Thus, an increase in the creep temperature agrees with the increase in the strain at the center of the tensioned semiconductor region.

In one or the other of the exemplary embodiments that have just been described, a stressing layer containing a material having a tensile strain, here in particular tensioned SiN, is provided. The method can also be applied for different stressing layers, for example containing material having a compressive strain such as amorphous carbon or TIN. The stressing layer can contain amorphous material or a layer of semiconductor material, for example SiGe, which is grown on the surface layer 12.

In the exemplary embodiment that has just been described, a tensioning of an initially relaxed or unstressed semiconductor region is provided. The method can also apply to an increase in a strain of a region already having a strain or even to a relaxation of an initially strained region. For example, a method as described above can be applied to the relaxation of a layer of silicon which is initially compressed for example by growth of SiGe followed by a condensation method or by providing a specific substrate.

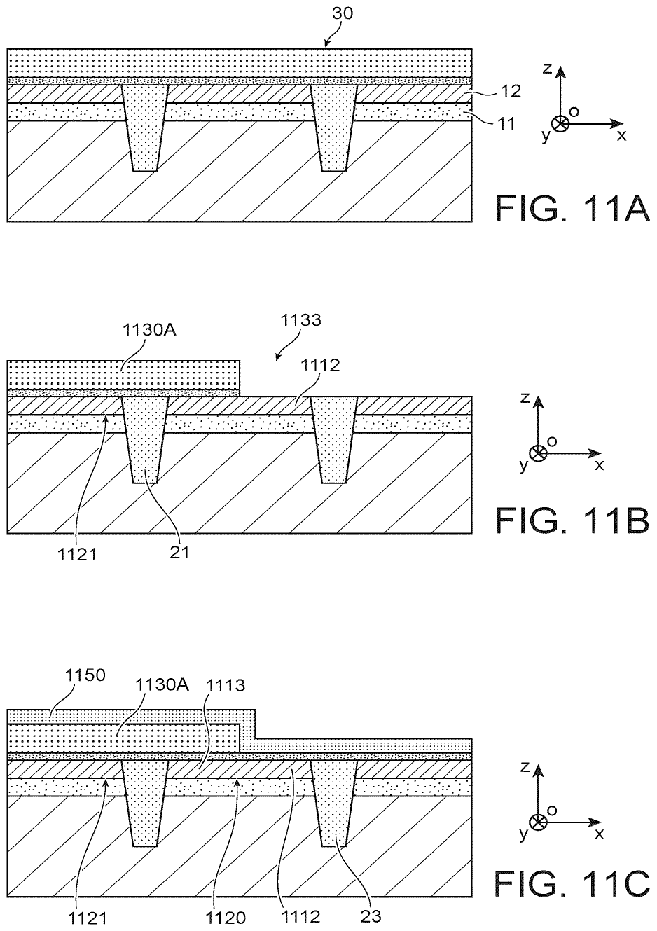

An alternative method for modifying the strain state of a semiconductor region 1120 belonging to a surface semiconductor layer 12 of a substrate of the semiconductor on insulator type is illustrated in FIGS. 11A-11C.

A “full wafer” deposition of a stressing layer 30 (FIG. 11A), that is to say over the entire extent of the substrate 5, is carried out. The stressing layer 30 can for example be a layer of SIN as described above.

An opening 1133 (FIG. 11B) is then formed in the stressing layer 30 facing a semiconductor region 1112 of said surface semiconductor layer 12 while preserving a portion 1130A of the stressing layer 30 facing a part of the substrate which is disposed against and in contact with the semiconductor region 1112. This part of the substrate covered by the portion 1130A comprises a distinct semiconductor zone 1121 and in this specific example separated from the semiconductor region 1112 via an isolation trench 21.

A second stressing layer 1150 is then deposited (FIG. 11C) on the stressing layer 30 as well as on the semiconductor region 1112 exposed by the opening 1133. According to a specific exemplary embodiment, the second stressing layer 1150 can also contain silicon nitride (SiₓN_{y}) with a tensile intrinsic strain, for example between 0.5 GPa and 1.5 GPa for a thickness which can be for example between 20 nm and 100 nm. Alternatively, it is possible to provide the stressing layers 30, 1150 with different thicknesses and/or containing different respective materials.

A creep annealing is then carried out according to a duration and a temperature adapted to allow the creep of the insulating layer 11 of the substrate and relax both the portion 1130A of the stressing layer 30 and the second stressing layer 1150.

With such an alternative, it is possible to obtain a semiconductor zone 1120 having a strain that is asymmetrical or at least unevenly distributed between the isolation trenches 21 insofar as, during the creep annealing, the semiconductor region 1112 is coated only with the second stressing layer 1150, while another region 1113 is coated with a stack of the stressing layers 30, 1150.

With such an alternative, active zones with different respective stresses can also be obtained. A semiconductor zone 1120, here facing only the second stressing layer 1150, and another semiconductor zone 1121 facing a stack of the portion 1130A and second layer 1150 have, after the creep annealing, different strain states.

To implement semiconductor zones with different stresses in the surface layer 12 of the same substrate, according to an alternative embodiment the stressing layer 30 is created on one part of the substrate and, on another part of the substrate, a second stressing layer 1230 different from the stressing layer 30 and in particular containing another material is created.

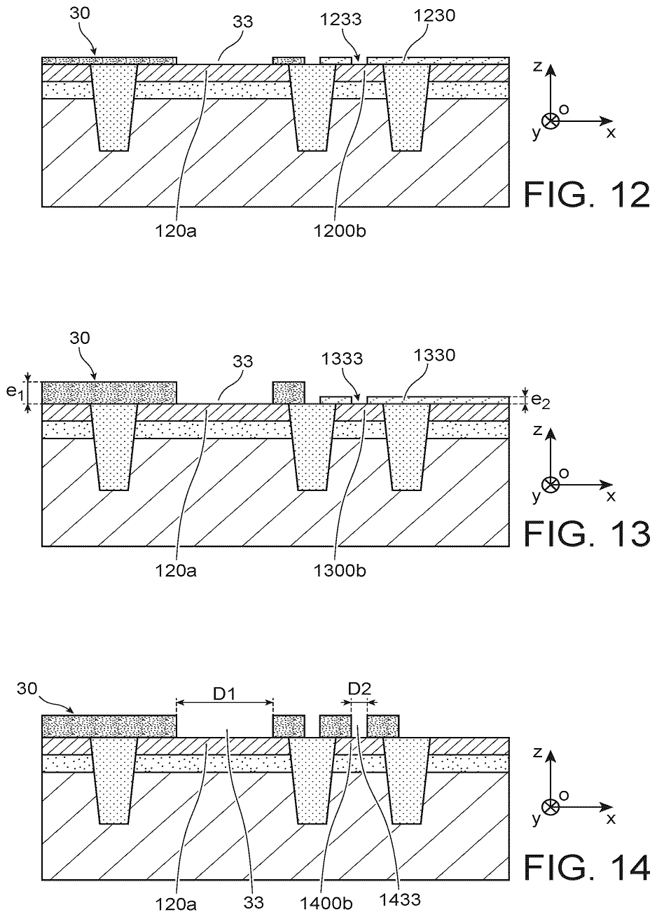

In the exemplary embodiment illustrated in FIG. 12, an opening 33 is made in the stressing layer 30, for example made of silicon nitride, facing a semiconductor region 120a of the surface layer 12. In a second stressing layer 1230, for example made of amorphous carbon or made of TIN, an opening 1233 is made facing another semiconductor region 1200b of said surface semiconductor layer. Once these openings 1233, 33 have been formed, at least an annealing is carried out to allow to carry out the creep of the insulating layer 11 and relax the preserved portions of the stressing layers 30, 1230. The respective stresses in the semiconductor regions 120a, 1200b are thus modified.

In another exemplary embodiment illustrated in FIG. 13, a stressing layer 30, for example made of silicon nitride, and in which an opening 33 is made, is provided with a first thickness e₁, for example between 20 nm and 100 nm. Another stressing layer 1330 with an opening 1333 is provided with a second thickness e₂, for example between 20 nm and 100 nm, and which is different from the first thickness e₁.

The stressing layers 30 and 1330 here can contain the same material, for example SiN having a tensile strain. A creep annealing of the insulating layer 11 is then carried out, which allows to relax the remaining portions of the layers 30 and 1330 and modify the state of the semiconductor region 120a facing the opening 33 and of the other region 1300b facing the other opening 1333.

It is thus possible to obtain different strain levels respectively in a semiconductor region 120a facing the opening 33 and in another region 1300b facing the other opening 1333 practiced in the stressing layer having a smaller thickness. With such an alternative, by adjusting the respective thicknesses e₁, e₂ according to the dimensions of the active zones, it is also possible to obtain identical strains in various active zones despite different respective sizes of these active zones.

It is also possible, as an alternative to the examples that have just been described in connection with FIGS. 12 and 13, to create stressing layers on various parts of the same substrate having both different thicknesses and different materials.

In another exemplary embodiment illustrated in FIG. 14, the stressing layer 30 comprises an opening 33 having a first critical dimension D1 and another opening 1433 having a second critical dimension D2 different from the first D1. “Critical dimension” means the smallest dimension of a pattern, here of an opening, measured parallel to the plane [O; x; y] of the coordinate system [O; x; y; z] except its height (measured parallel to the axis z).

Once these openings 1433, 33 have been made, the annealing is carried out to allow to carry out the creep of the insulating layer 11 and relax the preserved portions of the stressing layer 30, in order to modify the strain in semiconductor regions 120a, 1400b located facing the opening 33 and the other opening 1433, respectively. It is thus possible to obtain, in this example, different strains in the semiconductor region 120a facing the opening 33 and in the other region 1400b facing the other opening 1433, respectively.

Here again, with such an alternative, by adjusting the respective dimensions D1, D2 according to those of the dimensions of the active zones, it is also possible to obtain identical strains in various active zones despite different respective sizes of these active zones.

1-14. (canceled)

15. A method for modifying a strain state of at least one semiconductor region of a semiconductor device, the method comprising:
coating a surface semiconductor layer of a semiconductor-on-insulator substrate with a stressing layer, the substrate including a support layer, an insulating layer on the support layer, and the surface semiconductor layer on the insulating layer, the surface semiconductor layer including isolation trenches filled with insulating material and arranged on opposite sides of an active semiconductor zone including a first semiconductor region;
forming, in the stressing layer, at least one opening extending through the stressing layer and facing the first semiconductor region while preserving at least one portion of the stressing layer on and facing a part of the substrate that is disposed against and in contact with the first semiconductor region; and
performing a creep annealing for a duration and at a temperature sufficient to allow creep of the insulating layer and relaxation of the preserved portion of the stressing layer so as to modify the strain state of the first semiconductor region.

16. The method of claim 15, wherein the opening facing the first semiconductor region is centered between a first isolation trench and a second isolation trench disposed on opposite sides of the first semiconductor region.

17. The method of claim 15, wherein the part of the substrate facing the preserved portion of the stressing layer is a second semiconductor region disposed against and in contact with the first semiconductor region, and wherein the opening is formed to preserve an additional portion of the stressing layer facing at least a third semiconductor region disposed against and in contact with the first semiconductor region, the preserved portion and the additional portion being arranged on opposite sides of the opening, and the second semiconductor region and the third semiconductor region being disposed on opposite sides of the first semiconductor region.

18. The method of claim 17, wherein the stressing layer is under tensile strain, and wherein the creep annealing causes compression of the second semiconductor region and the third semiconductor region so as to place the first semiconductor region under tensile strain.

19. The method of claim 15, wherein the first semiconductor region is part of an active semiconductor zone configured for at least one N-type transistor, and wherein the opening is formed to preserve a portion of the stressing layer facing another active semiconductor zone configured for one or more P-type transistors.

20. The method of claim 15, further comprising, after forming the opening and before performing the creep annealing, depositing a second stressing layer on the stressing layer and on the first semiconductor region.

21. The method of claim 15, further comprising forming a second opening through the stressing layer to expose another semiconductor region of the surface semiconductor layer, the opening and the second opening having different respective dimensions.

22. The method of claim 15, wherein, prior to the creep annealing, a portion of the substrate is coated with a second stressing layer that is different from the stressing layer and/or has a thickness different from that of the stressing layer, and wherein the method further comprises, prior to the creep annealing, forming at least one opening in the second stressing layer to expose another semiconductor region of the surface semiconductor layer.

23. The method of claim 15, wherein the stressing layer comprises silicon nitride under tensile strain.

24. The method of claim 15, wherein the stressing layer has a thickness between 20 nm and 100 nm.

25. The method of claim 15, wherein the creep annealing is performed at a temperature between 900° C. and 1200° C. for a duration between 1 minute and 30 minutes.

26. The method of claim 15, wherein the first semiconductor region comprises silicon, and wherein at least one other semiconductor region of the substrate coated by the stressing layer comprises SiₓGe₁₋ₓ, with 0<x<1.

27. The method of claim 26, wherein the at least one other semiconductor region is a germanium-enriched region of the surface semiconductor layer, the surface semiconductor layer comprising silicon, and wherein the method further comprises, before coating the surface semiconductor layer with the stressing layer:
forming a silicon-germanium block on the at least one other semiconductor region; and
thermally oxidizing the silicon-germanium block and the surface semiconductor layer to enrich the at least one other semiconductor region with germanium.

28. A method for manufacturing a semiconductor device including transistors, the method comprising:
performing the method of claim 15;
removing the stressing layer after the creep annealing; and
after removing the stressing layer, forming at least one transistor in the first semiconductor region and at least one additional transistor in another semiconductor region of the surface semiconductor layer.
